(19) United States
(12) Patent Application Publication
(10) Pub. No.: US 2026/0302387 A1
(43) Pub. Date: Oct. 1, 2026

(54) WIRELESS BATTERY MANAGEMENT SYSTEM AND OPERATING METHOD THEREFOR

(71) Applicants: Hyundai Motor Company, Seoul (KR); Kia Corporation, Seoul (KR)

(72) Inventor: Beomgyu KIM, Hwaseong-SI (KR)

(21) Appl. No.: 19/314,199

(22) Filed: Aug. 29, 2025

(30) Foreign Application Priority Data
Mar. 25, 2025 (KR) 10-2025-0037684

(51) Int. Cl. H01M 10/42; G01R 31/371; G01R 31/388; H01M 10/48

(52) U.S. Cl. CPC H01M 10/425; G01R 31/371; G01R 31/388; H01M 10/48; H01M 2010/4271; H01M 2010/4278

(57) ABSTRACT

A wireless battery management system may perform a method to manage a battery. A wireless battery management system may include a cell monitoring unit (CMU) configured to measure a voltage of a battery cell in a battery system, and a battery management unit (BMU) configured to acquire, by wireless communication with the CMU, sensing data measuring the voltage of the battery cell. The BMU may be configured to, based on determining a momentary disconnection of a battery based on a battery pack voltage calculated from the sensing data, reset a state of charge (SOC) using a periodically stored SOC value.

### CROSS-REFERENCE TO RELATED APPLICATION

This present application claims the benefit of priority to Korean Patent Application No. 10-2025-0037684, filed on Mar. 25, 2025, in the Korean Intellectual Property Office, the entire disclosure of which is incorporated herein by reference.

### FIELD

The present disclosure relates to a wireless battery management system and an operating method therefor, and more particularly, to a wireless battery management system that resets a state of charge (SOC) when/if a momentary disconnection of the battery (B+) occurs, and an operating method therefor.

### BACKGROUND

Batteries (e.g., used in environmentally friendly vehicles such as electric vehicles (EVs), hybrid electric vehicles (HEVs), and plug-in hybrid electric vehicles (PHEVs)) may be high-voltage batteries that generate high voltage by connecting numerous battery cells (e.g., of the same specifications) in series and/or parallel.

A battery management system (BMS) is a device that may control and/or manage charging and discharging of such high-voltage batteries comprising numerous battery cells. A BMS may comprise a plurality of monitoring units (CMUs) that monitor the battery cells and/or a battery management unit (BMU) that manages the plurality of CMUs.

Battery management systems can be classified into wired battery management systems and wireless battery management systems, depending on the communication method between the plurality of CMUs and the BMU.

The wired battery management system may connect the plurality of CMUs and the BMU via wired cables, thus providing relatively stable communication. However, the wired battery management system may also use numerous cables and/or connectors, thus increasing the weight of the vehicle (e.g., by several tens of kilograms).

By contrast, the wireless battery management system may connect the plurality of CMUs and the BMU via wireless communication, thus significantly reducing the weight and volume of a battery pack. However, due to the inherent characteristics of wireless communication, the wireless battery management system may require a long time (e.g., 5 to 8 seconds) to initialize after a momentary disconnection of the battery (B+).

According to current logic standards, after a momentary disconnection of the battery (B+) and before connecting a main (+) relay of the battery system, the state of charge (SOC) of the battery should be reset based on an open circuit voltage (OCV) table using the battery pack voltage monitored for a very short time period (e.g., 400 ms to 500 ms). However, in wireless battery management systems, the OCV table cannot be used due to the long initialization time required.

When/if connecting the main (+) relay without knowing the battery pack voltage during the initialization process after a momentary disconnection of the battery (B+), there may be a risk of relay fusing caused by inrush current resulting from the creation of a discharge path when other high-voltage components fail.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

Systems, apparatuses, and methods are described for wireless battery management. A wireless battery management system may comprise: a wireless communication interface; a sensor device comprising one or more sensors configured to measure one or more voltages of one or more battery cells of a battery; and a battery management unit (BMU) comprising: a processor; and a memory storing at least one instruction that, when executed by the processor communicating with the memory, is configured to cause the BMU to: receive, from the sensing device via a wireless communication associated with the wireless communication interface, sensing data indicating the one or more voltages of the one or more battery cells, detect, based on the sensing data, a disconnection of the battery; based on the detected disconnection of the battery, reset a state of charge (SOC) using a stored SOC value, wherein the SOC is associated with the battery; and control, based on the reset SOC, one or more relay connections of the battery.

A battery management unit (BMU) may comprise: a processor; and a memory storing at least one instruction that, when executed by the processor communicating with the memory, is configured to cause the BMU to: receive, from at least one sensor via a wireless communication associated with a wireless communication interface, sensing data indicating a voltage of a battery cell in a battery; detect, based on a battery pack voltage determined from the sensing data, a momentary disconnection of the battery wherein the battery pack voltage is a voltage of a battery pack of the battery; based on the detected disconnection of the battery, reset a state of charge (SOC) using a stored SOC value, wherein the SOC is associated with the battery; and control, based on the reset SOC, one or more relay connections of the battery.

A method for operating a wireless battery management system may comprise: measuring, by a sensor device comprising at least one voltage sensor, a voltage of a battery cell in a battery; receiving, via a wireless communication from the sensor device and by a battery management unit (BMU) comprising a processor and a memory, sensing data indicating the measured voltage of the battery cell; detecting, based on the sensing data, a disconnection of the battery; resetting, by the BMU based on the detected disconnection of the battery, a state of charge (SOC) using a stored SOC value, wherein the SOC is associated with the battery; and controlling, based on the reset SOC, one or more relay connections of the battery.

The present disclosure is directed to providing a wireless battery management system that resets a state of charge (SOC) using a periodically stored SOC value when a momentary disconnection of the battery (B+) occurs, and an operating method therefor.

The present disclosure is further directed to providing a wireless battery management system that connects a main (+) relay of the battery system based on satisfaction of pre-charging completion conditions during the SOC reset process following a momentary disconnection of the battery (B+), and an operating method therefor.

Aspects of the present disclosure are not limited to those mentioned above, and other aspects and advantages not mentioned above will be understood from the following description, and become more apparent from the examples. Moreover, aspects of the present disclosure may be realized by the means and combinations thereof indicated in claims.

These and other features and advantages are described in greater detail below.

### BRIEF DESCRIPTION OF THE DRAWINGS

The foregoing and other aspects, as well as the following detailed description of the examples, should be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a diagram illustrating a battery system structure according to one example of the present disclosure.

FIG. 2 is a diagram illustrating a relay connection sequence in the battery system structure according to one example of the present disclosure.

FIG. 3 is a diagram illustrating an operation method of a BMU under normal use conditions versus conditions of momentary disconnection of the battery (B+), according to one example of the present disclosure.

FIG. 4 is a configuration diagram of a wireless battery management system according to one example of the present disclosure.

FIG. 5 is a diagram illustrating an SOC value storage method of a data flash according to one example of the present disclosure.

FIG. 6 is a flowchart illustrating a method for operating a wireless battery management system according to one example of the present disclosure.

### DETAILED DESCRIPTION

Examples disclosed in the present specification will be described in greater detail with reference to the accompanying drawings, and throughout the accompanying drawings, the same reference numerals are used to designate the same or similar components and redundant descriptions thereof are omitted. As used herein, the terms “module” and “unit” used to refer to components are used interchangeably in consideration of convenience of explanation, and thus, the terms per se should not be considered as having different meanings or functions. In relation to describing the present disclosure, when the detailed description of the relevant known technology is determined to unnecessarily obscure the gist of the present disclosure, the detailed description may be omitted. Furthermore, it should be understood that the appended drawings are intended only to help understand examples disclosed in the present document and do not limit the technical principles and scope of the present disclosure. Rather, it should be understood that the appended drawings include all of the modifications, equivalents or substitutes described by the technical principles and belonging to the technical scope of the present disclosure.

Although the terms first, second, third, and the like may be used herein to describe various elements, components, regions, layers, and/or sections, these elements, components, regions, layers, and/or sections should not be limited by these terms. These terms are only used to distinguish one element from another.

When an element or layer is referred to as being “on,” “engaged to,” “connected to,” or “coupled to” another element or layer, it may be directly on, engaged, connected, or coupled to the other element or layer, or intervening elements and/or layers may be present. In contrast, when an element is referred to as being “directly on,” “directly engaged to,” “directly connected to,” or “directly coupled to” another element or layer, there may be no intervening elements or layers present.

The term “unit” or “module” used in this specification signifies a unit that processes at least one function or operation, and may be realized by hardware, software, or a combination thereof. The operations of the method or the functions described in connection with the forms disclosed herein may be embodied directly in a hardware or a software module executed by a processor, or in a combination thereof. For example, the “module” or “unit” or one or more control devices (e.g., a controller, a control unit, a device described herein to transmit a control signal, etc.) may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like.

In general, throughout the present disclosure, references to components, units, or modules generally refer to items that logically can be grouped together to perform a function or group of related functions. Like reference numerals are generally intended to refer to the same or similar components. Components, units, and modules may be implemented in software, hardware or a combination of software and hardware. The components, units, modules, and/or functions described above may be implemented and/or performed by one or more processors. For examples, the components, units, and/or modules may include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The components, units, and/or modules may also include software control module(s) implemented with a processor or logic circuitry for example. The components, units, and/or modules may include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. One or more storage type media may include any or all of the tangible memory of computers, processors, or the like, or associated modules thereof, such as various semiconductor memories, tape drives, disk drives and the like, which may provide non-transitory storage at any time for software programming.

Depending on the context, the expression “configured to” as used herein may have meanings such as “set to”, “with the ability to”, “modified to”, “made to”, “to be able to”, etc. This expression is not limited to the meaning of “specially designed in hardware to”. For example, a processor configured to perform a specific operation may refer to a generic purpose processor capable of performing the specific operation by executing software, or to a special purpose computer structured through programming to perform the specific operation.

The expression “based on” as used herein is intended to describe one or more factors that influence an act or operation of determining or deciding described in a phrase or sentence including that expression, and this expression does not exclude any additional factors that influence the act or operation of determining or deciding.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B. The exemplary phrase “one or more of” is synonymous with “at least one of.”

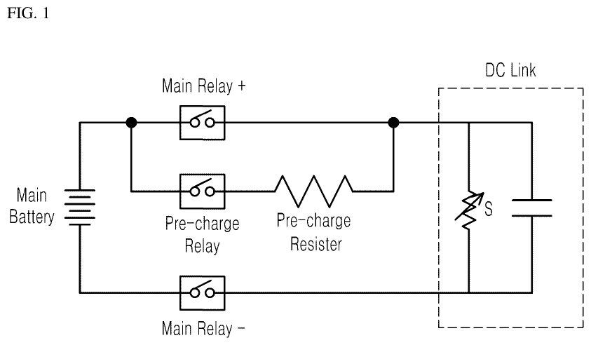

Hereinafter, a wireless battery management system and an operating method therefor according to the present disclosure will be described in detail with reference to FIGS. 1 to 6.

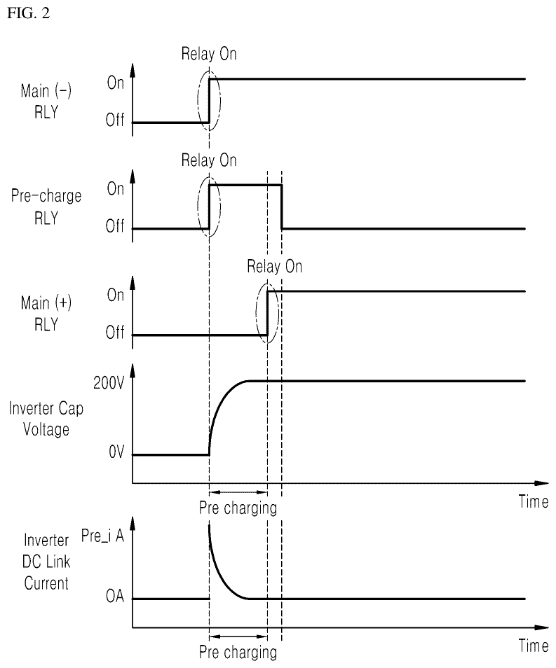

First, a battery system structure according to one example of the present disclosure and a relay connection sequence according thereto will be described with reference to FIGS. 1 and 2.

FIG. 1 is a diagram illustrating a battery system structure according to one example of the present disclosure, and FIG. 2 is a diagram illustrating a relay connection sequence in the battery system structure according to one example of the present disclosure.

Referring to FIG. 1, the battery system structure according to an example of the present disclosure may include a main (−) relay (Main Relay −), a pre-charge relay, a main (+) relay (Main Relay +), a pre-charge resistor, and a battery current sensor(S).

The battery current sensor(S) may measure the current value (inverter DC link current) of a DC link terminal of an inverter.

Referring to FIG. 2, in the battery system structure according to an example of the present disclosure, the main (−) relay and the pre-charge relay are connected/closed, and when the pre-charge relay is connected/closed, voltage is applied to the DC link terminal, charging the capacitor in the DC link terminal with voltage (invertor cap).

When/if a certain (e.g., threshold) level (e.g., 95%) or more of voltage based on the battery pack (cell sum) voltage is charged to the capacitor of the DC link terminal (e.g., if the voltage charged to the capacitor of the DC link terminal satisfies the threshold voltage) level, the main (+) relay may be connected/closed (e.g., only if the threshold voltage is satisfied by the voltage). See relay on timing for Main (+) in FIG. 2

However, if the main (+) relay is connected/closed and there is a large difference between the battery pack voltage and the voltage charged to the capacitor of the DC link terminal, this could result in relay fusing due to inrush current caused by the creation of a discharge path when other high-voltage components fail.

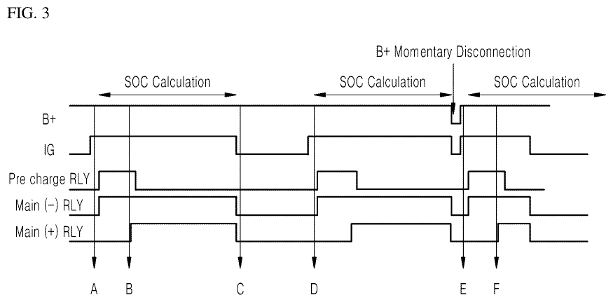

Hereinafter, an operation method of a BMU according to one example of the present disclosure will be described with reference to FIG. 3.

FIG. 3 is a diagram illustrating an operation method of a BMU under normal use conditions versus conditions of momentary disconnection of the battery (B+), according to one example of the present disclosure.

Referring to FIG. 3, for normal use conditions according to an example of the present disclosure, at a time when (if/when) an ignition device (IG) is turned on (see point A in FIG. 3), sensing data measuring the battery cell voltage may be acquired from a CMU via wireless communication. For example, the battery cell voltage may be measured by one or more sensors (e.g., a current sensor, a voltage sensor, a temperature sensor (thermistors, resistance temperature sensors), an impedance/conductance sensor, an integrated battery management ICs, etc.) of and/or in communication with the CMU. The CMU may acquire the sensing data from the one or more sensors and/or based on the measurements from the one or more sensors. The battery pack voltage may be determined/calculated based on (e.g., as) the sum of the acquired sensing data. The SOC value may be determined/calculated based on the battery pack voltage. The SOC value may be determined/calculated periodically (e.g., according to a storage cycle). The SOC value may be stored in a memory (e.g., a dedicated memory area allocated in a data flash). The SOC value may be stored periodically and/or based on determining that the SOC value has changed relative to a stored SOC value, for example.

For example, in an example of the present disclosure, the determination/calculation of the SOC value may apply current integration/voltage correction that corrects the error of the Coulomb Counter method (e.g., when/if determining/estimating the SOC value).

Also, or alternatively, the main (−) relay and pre-charge relay may be connected/closed (e.g., independently of the determining of the SOC value and storage of the SOC value). The main (−) relay and pre-charge relay being connected/closed may result in charging of the capacitor of the DC link terminal. Based on a determination that at least a threshold level (e.g., 95%) of the battery pack voltage is charged to the capacitor of the DC link terminal (e.g., due to the connection of the pre-charge relay), at that time/if that threshold level being satisfied (see point B in FIG. 3), the main (+) relay may be connected/closed to conduct current to a transmission line of the battery pack.

If/when the ignition device (IG) is turned off (see point C in FIG. 3), all relay connections may be released, and the SOC value (e.g., 60%) may be stored (e.g., in the dedicated memory area of the data flash).

For the conditions of momentary disconnection of the battery (B+), according to an example of the present disclosure, if/when the ignition device (IG) is turned on (see point D in FIG. 3), the SOC value (e.g., 60%) stored (e.g., in the data flash) at the time when the ignition device was turned off (see point C in FIG. 3) may be extracted/retrieved. Sensing data (e.g., measured/acquired by the one or more sensors of/associated with the CMU) indicating the battery cell voltage may be acquired (e.g., from the CMU via wireless communication). The battery pack voltage may be determined/calculated based on (e.g., as) the sum of the acquired sensing data.

Independent of other processes, SOC values may be periodically determined/calculated and stored in the dedicated memory area of the data flash.

After connecting the main (+) relay to conduct current to the transmission line of the battery pack, a momentary disconnection of the battery (B+) may be determined/detected (e.g., based on data/measurements received from the one or more sensors and/or an indication of disconnect based on the data/measurements). If/when the momentary disconnection of the battery (B+) is determined/detected (see point E in FIG. 3), the SOC value stored in the data flash may be extracted/retrieved and converted to a battery pack voltage for resetting the SOC.

If/when the momentary disconnection of the battery (B+) is determined (see point E in FIG. 3), an OCV table may not be usable (e.g., due to the long time required for initialization, such as due to the characteristics/wireless nature of the wireless battery management system). Accordingly, in the conditions of momentary disconnection of the battery (B+) according to one example of the present disclosure, initialization for the momentary disconnection of the battery (B+) may be performed using the SOC value stored in the memory (e.g., most recently in the dedicated memory area of the data flash).

If/when performing initialization using the SOC value stored (e.g., periodically stored in the dedicated memory area of the data flash), there may be conversion errors in the battery pack voltage determined/calculated from the SOC value.

In the conditions of momentary disconnection of the battery (B+) according to an example of the present disclosure, considering such conversion errors, the main (+) relay may be connected/closed at a time (see point F in FIG. 3) when satisfaction of pre-charging completion conditions are confirmed The satisfaction of the pre-charging completion conditions may be determined/confirmed using/based on the charging voltage of the capacitor (e.g., the sensor for measuring the voltage at the DC link terminal) and the current value acquired from the DC link terminal of the inverter (e.g., from a current sensor configured to measure/determine the current value at the DC link terminal).

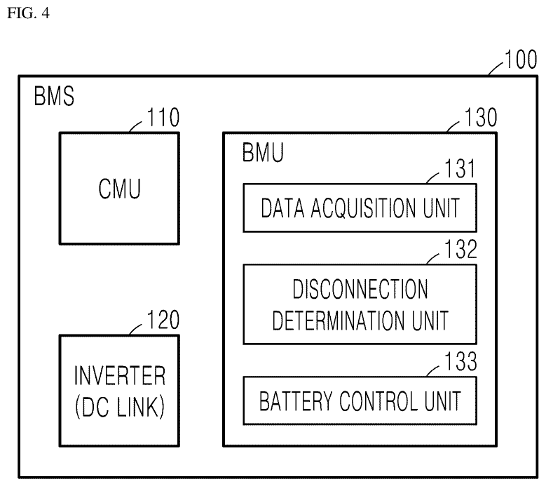

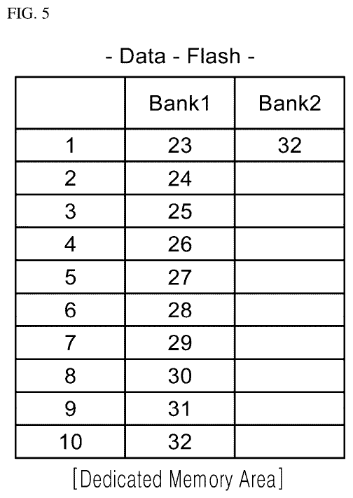

Hereinafter, with reference to FIGS. 4 and 5, a wireless battery management system according to an example of the present disclosure will be described, which implements the operation method of the BMU according to an example of the present disclosure as described herein.

FIG. 4 is a configuration diagram of a wireless battery management system according to one example of the present disclosure, and FIG. 5 is a diagram illustrating an SOC value storage method of a data flash according to one example of the present disclosure.

Referring to FIG. 4, a wireless battery management system (100) according to one example of the present disclosure may include a cell monitoring unit (CMU, 110) configured to measure a voltage of a battery cell in the battery system, an inverter (120) configured to convert direct current power of the battery system to alternating current power, and a battery management unit (BMU, 130) configured to acquire, via wireless communication with the CMU, sensing data indicating the voltage of the battery cell. The sensing data may be based on measurements from a sensor configured to measure/determine the voltage of the battery cell.

The BMU (130) may, based on determining a momentary disconnection of the battery (e.g., based on the battery pack voltage determined/calculated by summing the sensing data), reset the state of charge (SOC) using a (e.g., periodically) stored SOC value.

The BMU (130), according to one example of the present disclosure, may include a data acquisition unit (131), a disconnection determination unit (132), and/or a battery control unit (133).

The data acquisition unit (131) may be configured to acquire, via/over wireless communication from the CMU (110), sensing data indicating the battery cell voltage in the battery system. The sensing data may be based on measurements acquired by a voltage sensor, for example.

The disconnection determination unit (132) may be configured to determine/calculate the battery pack voltage based on the sensing data acquired from the CMU (110) through the data acquisition unit (131). The disconnection determination unit (132) may determine/detect a momentary disconnection of the battery (B+) based on a pattern of changes in the calculated battery pack voltage. A momentary disconnection of a battery may be detected as a phenomenon where the battery pack voltage changes instantaneously/sufficiently sharply.

The battery pack voltage based on the sensing data may be determined/calculated based on/by summing the sensing data received from the CMU (110).

The battery control unit (133) may be configured to, based on a momentary disconnection of the battery being detected/determined (e.g., by/through the disconnection determination unit (132)), reset the SOC using a stored SOC value (e.g. periodically/currently/most recently stored).

The battery control unit (133) may store an SOC value based on/corresponding to a time when the ignition device is turned off. The battery control unit (133) may also, or alternatively, store SOC values, after/if the ignition device is turned on, at points in time when each cycle elapses according to a storage cycle and/or based on determining a change in the SOC value relative to a stored SOC value. In this case, the battery control unit (113) may sequentially store SOC values in a dedicated memory area allocated in the data flash (e.g., overriding a stored SOC value with a most recent SOC value).

In the case of rapid charging (e.g., one step), which currently has the most severe SOC changes, 2.75 C may be used, which takes about 13 seconds per 1%. Even considering a 3-4 C current for charging, about 9 seconds would be expected per 1% charge. Therefore, considering a target SOC accuracy requirement of 5%, for example, an error exceeding 5% could occur within 1 minute. To achieve a higher accuracy requirement of within 1%, the SOC value storage cycle may be set to, for example, less than 10 seconds.

The dedicated memory (e.g., area of the data flash) in which SOC values are (e.g., sequentially) stored may be designed to consider the characteristic of a data flash where a number of data deletions affects the memory endurance life. For this purpose, the dedicated memory area allocated in the data flash may be divided into a plurality of banks.

Referring to FIG. 5, the dedicated memory area of the data flash according to one example of the present disclosure may be divided into, for example, a first bank (Bank 1) and a second bank (Bank 2).

In such case, when/if SOC values need to be stored first in the first bank according to the storage order, the battery control unit (133) may sequentially store SOC values in the first bank, and based on the storage capacity of the first bank being exceeded/filled, switch from the first bank to the second bank and store the next SOC value in the second bank.

When/if the dedicated memory area is switched from the first bank to the second bank (e.g., according to the storage order) the SOC value is stored in the second bank (e.g., the first entry in the second bank is filled), the battery control unit (133) may secure new storage capacity by erasing the existing SOC values sequentially stored in the first bank.

If/when SOC reset due to a momentary disconnection of the battery (+) is not needed after the ignition device (IG) is turned on, the battery control unit (133) may extract the SOC value properly stored in the data flash, and read the dedicated memory area of the data flash (e.g., Bank 1 and/or Bank 2) to identify the memory location for periodically storing SOC values according to the storage cycle.

If/when the memory location for periodically storing SOC values is confirmed/identified, the battery control unit (133) may acquire sensing data indicating the battery cell voltage via wireless communication from the CMU (110) (e.g., which may have received the sensing data from the sensor configured to measure the battery cell voltage). The battery control unit (133) may determine/calculate the battery pack voltage based on/as the sum of the acquired sensing data.

If/when SOC reset is needed (e.g., due to a determination of a momentary disconnection of the battery (+), which may be made based on detecting the battery pack voltage changes instantaneously/suddenly and/or based on a pattern of changes in the battery pack voltage determined via the disconnection determination unit (132) after the ignition device is turned), the battery control unit (133) may read the dedicated memory area of the data flash (e.g., Bank 1 and/or Bank 2) and extract/retrieve a last-stored SOC value. The battery control unit (133) may determine/calculate the battery pack voltage using/based on the extracted/retrieved SOC value for the resetting of the SOC.

The battery control unit (133) may connect the main (−) relay and the pre-charge relay to charge voltage (inverter cap) to the capacitor of the DC link terminal. Based on the charging the voltage to the capacitor of the DC link terminal (e.g., based on determining an amount charged), the battery control unit (133) may determine whether to connect the main (+) relay of the battery system according to the pre-charging completion conditions. The pre-charging completion conditions may be based on/determined using the charging voltage of the capacitor and the current value acquired from the DC link terminal.

The battery control unit (133) may determine that the pre-charging completion conditions are satisfied. Based on the pre-charging conditions being satisfied, the battery control unit (133) may connect the main (+) relay of the battery system (e.g., if/when both the difference between the battery pack voltage and the charging voltage of the capacitor falls within a threshold range, and the current value acquired from the DC link terminal of the inverter falls within a threshold range with reference to 0 amperes (A)).

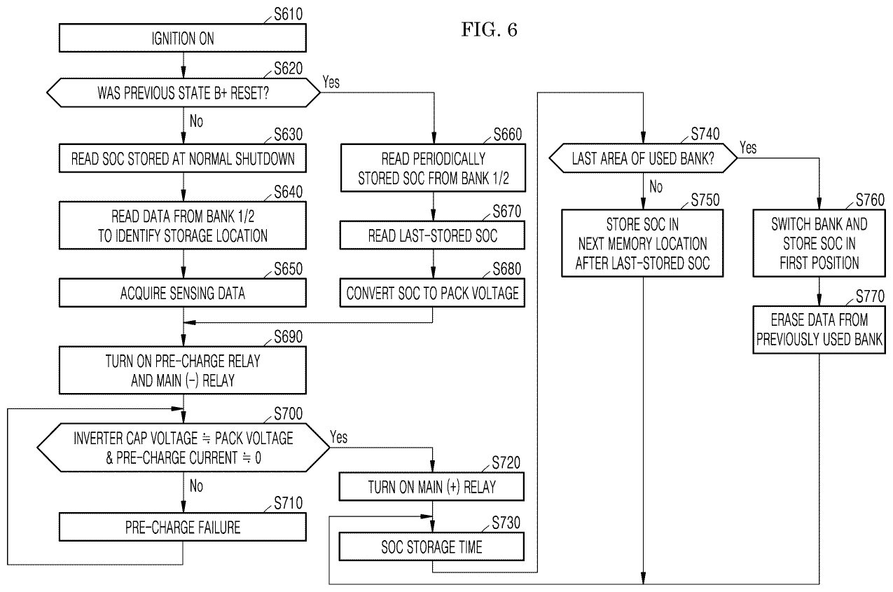

A method for operating a wireless battery management system according to one example of the present disclosure will be described with reference to FIG. 6.

FIG. 6 is a flowchart illustrating a method for operating a wireless battery management system according to one example of the present disclosure. For convenience, FIG. 6 is described by way of an example in which the steps are performed by a processor circuit. One, some, or all steps of the example method of FIG. 6, or portions thereof, may be performed by one or more other circuits. One or some, steps of the example method of FIG. 6 may be omitted, performed in other orders, and/or otherwise modified, and/or one or more additional steps may be added.

In the following description, it is assumed that the dedicated memory area allocated in the data flash in this example of the present disclosure is divided into a first bank (Bank 1) and a second bank (Bank 2) as described above, and SOC values need to be stored first in the first bank according to the storage order.

The ignition device (IG) may be turned on (S610) If/when the ignition device (IG) is turned on, the BMU (130) may determine whether SOC reset is needed due to a momentary disconnection of the battery (+) (S620).

Based on a determination that SOC reset is not needed due to a momentary disconnection of the battery (+) (S620—No), the BMU (130) may extract the SOC value that has been normally stored in the data flash (S630). The, dedicated memory area of the data flash (e.g., Bank 1/Bank 2) may be read to identify the memory location for periodically storing SOC values according to the storage cycle (S640).

If/when the memory location for periodically storing SOC values is identified, the BMU (130) may acquire sensing data indicating the battery cell voltage (e.g., via wireless communication from the CMU (110) and/or sensor), and/or determine/calculate the battery pack voltage based on/as the sum of the sensing data (S650).

Based on a determination that SOC reset is needed because a momentary disconnection of the battery (B+) (e.g., which may be a phenomenon where the battery pack voltage changes instantaneously) has been determined based on a pattern of changes in the battery pack voltage (e.g., S620—Yes), the battery control unit (133) may read the dedicated memory area of the data flash (e.g., Bank 1/Bank 2) (S660). The last-stored SOC may be extracted/retrieved (S670).

The BMU (130) may determine/calculate the battery pack voltage for the resetting of the SOC using the SOC value extracted from the dedicated memory area of the data flash (e.g., Bank 1/Bank 2) (S680).

The BMU (130) may connect the main (−) relay and the pre-charge relay to charge voltage (inverter cap) to the capacitor of the DC link terminal (S690).

The BMU (130) may determine whether to connect the main (+) relay of the battery system according to the pre-charging completion conditions using the charging voltage of the capacitor acquired from the DC link terminal and the current value acquired from the DC link terminal (S700).

If the difference between the battery pack voltage and the charging voltage of the capacitor does not fall within a threshold range, and/or if the current value acquired from the DC link terminal of the inverter does not fall within a threshold range with reference to 0 amperes (A) (S700—No), the BMU (130) may determine a pre-charge failure (S710).

If the difference between the battery pack voltage and the charging voltage of the capacitor falls within the threshold range, and also if the current value acquired from the DC link terminal of the inverter falls within the threshold range with reference to 0 amperes (A) (S700—Yes), the BMU (130) may determine that the pre-charging completion conditions are satisfied and connect the main (+) relay of the battery system (S720).

If/when the time to store the SOC value arrives (e.g., according to the storage cycle), the BMU (130) may store the SOC value at points in time when each cycle elapses according to the storage cycle, in which case it follows the method of sequentially storing SOC values in a dedicated memory area allocated in the data flash (S730).

The BMU (130) may determine whether storage capacity exists in the first bank according to the storage order (S740). The BMU (130) may determine whether the area where the SOC value was stored in the previous storage cycle is the last area of the first bank, (the first bank may be the current bank being filled).

Based on the area where the SOC value was stored in the previous storage cycle not being the last storage area of the first bank (S740—No), the BMU (130) may sequentially store SOC values in a next storage area of the first bank S750).

Based on the area where the SOC value was stored in the previous storage cycle being the last storage area of the first bank (S740—Yes), the BMU (130) may switch from the first bank to the second bank and store the next SOC value in the second bank (S760).

When/if the dedicated memory area is switched from the first bank to the second bank according to the storage order and the SOC value is initially (first) stored in the second bank, in step S770, the BMU (130) may secure new storage capacity by erasing the existing SOC values sequentially stored in the first bank (S770). The second bank will then be considered the first bank, and the empty bank will be considered the second bank.

A wireless battery management system according to one aspect of the present disclosure may include a cell monitoring unit (CMU) configured to measure a voltage of a battery cell in a battery system, and a battery management unit (BMU) configured to receive, through wireless communication with the CMU, sensing data measuring the voltage of the battery cell, wherein the BMU is configured to, based on determining a momentary disconnection of a battery based on a battery pack voltage determined from the sensing data, reset a state of charge (SOC) using a periodically stored SOC value.

The BMU may be configured to sequentially store SOC values according to a storage cycle after an ignition device is turned on, and based on determining the momentary disconnection of the battery, calculate a battery pack voltage using a last-stored SOC value for the resetting of the SOC.

The wireless battery management system may further include an inverter configured to convert direct current power of the battery system to alternating current power, and the BMU may be configured to connect/close a main (+) relay of the battery system based on satisfaction of pre-charging completion conditions using a charging voltage of a capacitor and a current value, both received from a DC link terminal of the inverter.

A battery management unit (BMU) with wireless communication capability according to another aspect of the present disclosure may include a data acquisition unit configured to receive, through wireless communication, sensing data measuring a voltage of a battery cell in a battery system, a disconnection determination unit configured to determine a momentary disconnection of a battery based on a battery pack voltage determined from the sensing data, and a battery control unit configured to, based on the momentary disconnection of the battery being determined, reset a state of charge (SOC) using a periodically stored SOC value.

The battery control unit may be configured to store at least one of an SOC value at a point in time when an ignition device is turned off, or SOC values, after the ignition device is turned on, at points in time when each cycle elapses according to a storage cycle.

The battery control unit may be configured to sequentially store SOC values in a dedicated memory area allocated in data flash.

The dedicated memory area may include two or more banks for sequential storage of the SOC values.

The battery control unit may be configured to, In a case of where the two or more banks include a first bank and a second bank and the SOC values are to be stored first in the first bank according to a storage order, sequentially store the SOC values in the first bank, and based on a storage capacity of the first bank being exceeded, switch from the first bank to the second bank, initially store a next SOC value in the second bank, and erase existing SOC values stored in the first bank.

The battery control unit may be configured to, based on determining the momentary disconnection of the battery, calculate a battery pack voltage using a last-stored SOC value for the resetting of the SOC.

The battery control unit may be configured to, in a case of where calculating the battery pack voltage for the resetting of the SOC using the periodically stored SOC value, compare the battery pack voltage calculated using the periodically stored SOC value with a charging voltage of a capacitor received from a DC link terminal of an inverter included in the battery management system.

The battery control unit may be configured to connect a main (+) relay of the battery system based on a difference between the battery pack voltage calculated using the periodically stored SOC value and the charging voltage of the capacitor falling within a threshold range.

The battery control unit may be configured to connect a main (+) relay of the battery system based on a current value received from the DC link terminal of the inverter falling within a threshold range with reference to 0 amperes (A).

A method for operating a wireless battery management system according to another aspect of the present disclosure may include measuring, by a cell monitoring unit (CMU), a voltage of a battery cell in a battery system, receiving, by a battery management unit (BMU), through wireless communication with the CMU, sensing data measuring the voltage of the battery cell, and resetting, by the BMU, a state of charge (SOC) using periodically stored SOC values, based on determining a momentary disconnection of a battery based on a battery pack voltage calculated from the sensing data.

The resetting may include sequentially storing SOC values according to a storage cycle after an ignition device is turned on, and based on determining the momentary disconnection of the battery, calculating a battery pack voltage using a last-stored SOC value for the resetting of the SOC.

The method may further include connecting, by the BMU, a main (+) relay of the battery system based on satisfaction of pre-charging completion conditions using a charging voltage of a capacitor and a current value, both received from a DC link terminal of an inverter.

According to examples of the present disclosure, in resetting the SOC based on determining a momentary disconnection of the battery (B+), the SOC value periodically stored in the dedicated memory area of the data flash is used, and thus, initialization may be performed in a short time without an OCV table.

Furthermore, according to examples of the present disclosure, since the main (+) relay of the battery system is connected/closed based on satisfaction of pre-charging completion conditions during the process of resetting the SOC, relay fusing due to inrush current resulting from the creation of a discharge path when other high-voltage components fail may be prevented.

As used in the present disclosure (especially in the appended claims), the terms “a/an” and “the” include both singular and plural referents, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof (“for example”, “such as”) are merely to describe the present disclosure in greater detail. Therefore, it should be understood that the scope of the present disclosure is not limited to the example examples described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example examples described above, and rather intended to include the following appended claims, and all modifications, equivalents, and alternatives falling within the spirit and scope of the following claims.

1. A wireless battery management system comprising:
a wireless communication interface;
a sensor device comprising one or more sensors configured to measure one or more voltages of one or more battery cells of a battery; and
a battery management unit (BMU) comprising:
a processor; and
a memory storing at least one instruction that, when executed by the processor communicating with the memory, is configured to cause the BMU to:
receive, from the sensing device via a wireless communication associated with the wireless communication interface, sensing data indicating the one or more voltages of the one or more battery cells,
detect, based on the sensing data, a disconnection of the battery;
based on the detected disconnection of the battery, reset a state of charge (SOC) using a stored SOC value, wherein the SOC is associated with the battery; and
control, based on the reset SOC, one or more relay connections of the battery.

2. The wireless battery management system of claim 1, wherein the at least one instruction, when executed by the processor, is further configured to cause the BMU to:
after an ignition device is turned on, sequentially store SOC values according to a storage cycle; and
based on detecting the disconnection of the battery, determine, based on a most recently stored SOC value, a battery pack voltage for the resetting of the SOC, wherein the battery pack voltage is a voltage of a battery pack of the battery.

3. The wireless battery management system of claim 1,
wherein the battery management system further comprises an inverter configured to convert direct current power of the battery to alternating current power, and
wherein the at least one instruction, when executed by the processor, is further configured to cause the BMU to:
determine, based on a current value and a charging voltage of a capacitor of a DC link terminal of the inverter, that a pre-charging completion condition is satisfied; and
close, based on the pre-charging completion condition being satisfied, a main (+) relay of the battery to connect a node of the battery with a node of the DC link.

4. A battery management unit (BMU), comprising:
a processor; and
a memory storing at least one instruction that, when executed by the processor communicating with the memory, is configured to cause the BMU to:
receive, from at least one sensor via a wireless communication associated with a wireless communication interface, sensing data indicating a voltage of a battery cell in a battery;
detect, based on a battery pack voltage determined from the sensing data, a momentary disconnection of the battery wherein the battery pack voltage is a voltage of a battery pack of the battery;
based on the detected disconnection of the battery, reset a state of charge (SOC) using a stored SOC value, wherein the SOC is associated with the battery; and
control, based on the reset SOC, one or more relay connections of the battery.

5. The BMU of claim 4, wherein the at least one instruction, when executed by the processor, is further configured to cause the BMU to store SOC values either based on an ignition device being turned off, or according to a storage cycle while the ignition device is turned on.

6. The BMU of claim 5, wherein the at least one instruction, when executed by the processor, is further configured to cause the BMU to sequentially store the SOC values in a dedicated memory area allocated in a data flash.

7. The BMU of claim 6, wherein the dedicated memory area comprises two or more banks for sequential storage of the SOC values.

8. The BMU of claim 7, wherein the two or more banks comprise a first bank and a second bank, and wherein the at least one instruction, when executed by the processor, is further configured to cause the BMU to:
sequentially store the SOC values first in the first bank according to a storage order; and
based on a storage capacity of the first bank being filled:
store a next SOC value, of the SOC values according to the storage order, in the second bank; and
erase the SOC values stored in the first bank.

9. The BMU of claim 4, wherein the at least one instruction, when executed by the processor, is further configured to cause the BMU to, based on detecting the disconnection of the battery, determine, based on a last-stored SOC value, the battery pack voltage.

10. The BMU of claim 9, wherein the at least one instruction, when executed by the processor, is further configured to cause the BMU to compare the battery pack voltage, determined based on the last-stored SOC value, with a charging voltage of a capacitor of a DC link terminal of an inverter, wherein the one or more relay connections are controlled based on the comparing.

11. The BMU of claim 10, wherein the at least one instruction, when executed by the processor, is further configured to cause the BMU to, based on the comparing indicating a difference between the battery pack voltage and the charging voltage of the capacitor falling within a threshold range, close a main (+) relay of the battery to connect a node of the battery with a node of the DC link.

12. The BMU of claim 10, wherein the at least one instruction, when executed by the processor, is further configured to cause the BMU to:
based on a current value, acquired from the DC link terminal, falling within a threshold range relative to 0 amperes (A), close a main (+) relay of the battery to connect a node of the battery with a node of the DC link.

13. A method for operating a wireless battery management system, the method comprising:
measuring, by a sensor device comprising at least one voltage sensor, a voltage of a battery cell in a battery;
receiving, via a wireless communication from the sensor device and by a battery management unit (BMU) comprising a processor and a memory, sensing data indicating the measured voltage of the battery cell;
detecting, based on the sensing data, a disconnection of the battery;
resetting, by the BMU based on the detected disconnection of the battery, a state of charge (SOC) using a stored SOC value, wherein the SOC is associated with the battery; and
controlling, based on the reset SOC, one or more relay connections of the battery.

14. The method of claim 13, further comprising:
based on an ignition device being turned on, sequentially storing SOC values according to a storage cycle; and
based on the detected disconnection of the battery, determining, based on a last-stored SOC value for the resetting of the SOC, a battery pack voltage, wherein the battery pack voltage is a voltage of a battery pack of the battery.

15. The method of claim 14, further comprising storing, based on the ignition device being turned off, an SOC value in sequence with the stored SOC values.

16. The method of claim 13, further comprising, based on detecting the disconnection of the battery, determining, based on a last-stored SOC, the battery pack voltage.

17. The method of claim 16, further comprising:
comparing the battery pack voltage with a charging voltage of a capacitor of a DC link terminal of an inverter of the battery, wherein the one or more relay connections are controlled based on the comparing.

18. The method of claim 14, wherein the sequentially storing the SOC values comprises sequentially storing the SOC values in one of a first bank or a second bank in a dedicated memory area allocated in a data flash.

19. The method of claim 18, wherein the sequentially storing the SOC values comprises:
sequentially storing the SOC values in the first bank;
based on a storage capacity of the first bank being filled, storing a next SOC value, or the SOC values according to a storage order, in the second bank; and
erasing the SOC values stored in the first bank.

20. The method of claim 13, further comprising:
receiving, from a DC link terminal of an inverter of the battery, a charging voltage of a capacitor of the DC link terminal and a current value;
determining, based on the charging voltage and the current value, that pre-charging completion conditions are satisfied; and
closing, by the BMU based on the pre-charging completion conditions being satisfied, a main (+) relay of the battery to connect a node of the battery with a node of the DC link.
